(19) United States
(12) Patent Application Publication
(10) Pub. No.: US 2025/0234498 A1
(43) Pub. Date: Jul. 17, 2025

(54) MODULAR MAGNETICALLY SHIELDED ROOM

(71) Applicant: FieldLine Inc., Boulder, CO (US)

(72) Inventors: Kenneth J. Hughes, Lafayette, CO (US); Kendall Dalton Holloway, Denver, CO (US); Gage Robert Barclay, Boulder, CO (US); Lance Michael Phillips, Monument, CO (US)

(21) Appl. No.: 18/409,946

(22) Filed: Jan. 11, 2024

(51) Int. Cl. H05K 9/00; E04B 1/92

(52) U.S. Cl. CPC H05K 9/0003; E04B 1/92; E04B 2001/925; E04B 2103/06

(57) ABSTRACT

Various embodiments comprise a modular magnetically shielded room to shield a magnetic field detection system from electromagnetic noise. In some examples, the magnetically shielded room comprises walls, a floor, and a ceiling that encloses an interior volume. The walls, floor, and ceiling comprise electrically conductive panels. Each panel comprises a flange to mechanically couple to adjacent panels. The mechanical coupling also electrically couples the panels. Electrically conductive backets are mechanically coupled to the flanges at the interfaces between the walls, floors, and ceiling. The mechanical coupling also electrically couples the brackets to the panels. Internal mu-metal panels are mounted to the internal surfaces of the electrically conductive panels of the walls, floor, and ceiling. External mu-metal panels are mounted to the external surfaces of the electrically conductive panels of the walls, floor, and ceiling.

### TECHNICAL FIELD

Various embodiments of the present technology relate to electromagnetic shielding, and more specifically, to modular magnetically shielded rooms for magnetic sensing operations.

### BACKGROUND

Magnetic field detection systems detect and characterize magnetic fields generated by a magnetic field source. The magnetic field detection systems comprise magnetometers that measure the field strength and/or direction of the magnetic fields to characterize the sensed fields. Exemplary magnetic field detection systems include Magnetoencephalography (MEG), Electroencephalography (EEG), Magnetoencephalography (MEG), Magnetocardiography (MCG), Magnetogastrography (MGG), Magnetomyography (MMG), and the like. Exemplary magnetometers include Optically Pumped Magnetometers (OPMs), gradiometers, nitrogen vacancy centers, Superconducting Quantum Interference Devices (SQUIDs), and the like. Typically, these magnetometers are very sensitive to magnetic fields. Moreover, the target magnetic fields produced by magnetic field sources sensed by the magnetic field detection systems are typically much weaker than background electromagnetic fields like the earth's magnetic field. Excessive background electromagnetic noise reduces the effectiveness of the magnetic field detection systems.

To account for the sensitivity of the magnetometers and the relative weakness of the target magnetic fields, the magnetic field detection systems are placed within magnetically shielded rooms. Magnetically shielded rooms comprise electrically conductive metal and magnetic shielding. The conductive metal may comprise copper, coated aluminum, and the like. The magnetic shielding may comprise mu-metal. The conductive metal and the magnetic shielding are arranged within the room to create a volume that minimizes or eliminates background electromagnetic noise. A magnetic field detection system may be placed within the shielded volume to increase the effectiveness of its magnetic sensing operations. Conventional magnetically shielded rooms are static structures. The cost to construct these structures can be excessive and the structures themselves are difficult to build. Unfortunately, conventional magnetically shielded rooms are not efficiently constructed.

### Overview

This Overview is provided to introduce a selection of concepts in a simplified form that are further described below in the Technical Description. This summary is not intended to identify key features or essential features of the claimed subject matter, nor is it intended to be used as an aid in determining the scope of the claimed subject matter.

Various embodiments of the present technology relate to electromagnetic shielding. Some embodiments comprise a modular magnetically shielded room to shield a magnetic field detection system from electromagnetic interference. The magnetically shielded room comprises walls, a floor, and a ceiling enclosing an interior volume. The walls, floor, and ceiling each comprise electrically conductive panels. The electrically conductive panels comprise flanges to mechanically couple to adjacent panels. Mechanically coupling the panels to each other electrically couples the panels. Electrically conductive brackets mechanically couple to the flanges of the electrically conductive panels at the interfaces between the walls, the floor, and the ceiling. Mechanically coupling the brackets to the panels electrically couples the brackets and the panels. Internal mu-metal panels are mounted to the internal surfaces of the electrically conductive panels of the walls, the floor, and the ceiling. External mu-metal panels are mounted to the external surfaces of the electrically conductive panels of the walls, the floor, and the ceiling.

Some embodiments comprise a method of manufacturing a modular magnetically shielded room to shield a magnetic field detection system from electromagnetic interference. The method of manufacturing comprises mechanically coupling electrically conductive panels to each other to form walls, a floor, and a ceiling of the modular magnetically shielded room. Mechanically coupling the electrically conductive panels to each other electrically couples the electrically conductive panels to each other. The method further comprises mechanically coupling electrically conductive brackets to the electrically conductive panels at the interfaces between the walls, the floor, and the ceiling to couple the walls, the floor, and the ceiling to each other. Mechanically coupling the electrically conductive brackets to the electrically conductive panels electrically couples the electrically conductive brackets to the electrically conductive panels. The method further comprises mounting internal mu-metal panels to the internal surfaces of the electrically conductive panels of the walls, the floor, and the ceiling. The method further comprises mounting external mu-metal panels to the external surfaces of the electrically conductive panels of the walls, the floor, and the ceiling.

### DESCRIPTION OF THE DRAWINGS

Many aspects of the disclosure can be better understood with reference to the following drawings. The components in the drawings are not necessarily drawn to scale. Moreover, in the drawings, like reference numerals designate corresponding parts throughout the several views. While several embodiments are described in connection with these drawings, the disclosure is not limited to the embodiments disclosed herein. On the contrary, the intent is to cover all alternatives, modifications, and equivalents.

FIG. 1 illustrates an exemplary modular magnetically shielded room.

FIG. 2 illustrates an example of structural panels of the modular magnetically shielded room.

FIG. 3 further illustrates the modular magnetically shielded room.

FIG. 4 further illustrates the modular magnetically shielded room.

FIG. 5 illustrates an example of interior mu-metal panels of the modular magnetically shielded room.

FIG. 6 further illustrates the interior mu-metal panels of the modular magnetically shielded room.

FIG. 7 further illustrates the interior mu-metal panels of the modular magnetically shielded room.

FIG. 8 further illustrates the modular magnetically shielded room.

FIG. 9 illustrates an example of exterior mu-metal panels of the modular magnetically shielded room.

FIG. 10 further illustrates the exterior mu-metal panels of the modular magnetically shielded room.

FIG. 11 further illustrates the modular magnetically shielded room.

FIG. 12 further illustrates the modular magnetically shielded room.

FIG. 13 further illustrates the modular magnetically shielded room.

FIG. 14 illustrates an example of a door of the modular magnetically shielded room.

FIG. 15 further illustrates the modular magnetically shielded room.

FIG. 16 further illustrates the modular magnetically shielded room.

FIG. 17 illustrates an exemplary modular magnetically shielded room.

FIG. 18 illustrates an example of an electrically conductive aluminum panel and an electrically conductive aluminum bracket for the modular magnetically shielded room.

FIG. 19 further illustrates the modular magnetically shielded room.

FIG. 20 further illustrates the modular magnetically shielded room.

FIG. 21 illustrates an example of mu-metal panels, mu-metal cover strips, and mu-metal brackets of the modular magnetically shielded room.

FIG. 22 further illustrates the modular magnetically shielded room.

FIG. 23 further illustrates the modular magnetically shielded room.

FIG. 24 further illustrates the modular magnetically shielded room.

FIG. 25 further illustrates the modular magnetically shielded room.

FIG. 26 illustrates an example of support feet of the modular magnetically shielded room.

FIG. 27 further illustrates the modular magnetically shielded room.

FIG. 28 illustrates an example of a waveguide for the modular magnetically shielded room.

FIG. 29 further illustrates the modular magnetically shielded room.

The drawings have not necessarily been drawn to scale. Similarly, some components or operations may not be separated into different blocks or combined into a single block for the purposes of discussion of some of the embodiments of the present technology. Moreover, while the technology is amendable to various modifications and alternative forms, specific embodiments have been shown by way of example in the drawings and are described in detail below. The intention, however, is not to limit the technology to the particular embodiments described. On the contrary, the technology is intended to cover all modifications, equivalents, and alternatives falling within the scope of the technology as defined by the appended claims.

### DETAILED DESCRIPTION

The following description and associated figures teach the best mode of the invention. For the purpose of teaching inventive principles, some conventional aspects of the best mode may be simplified or omitted. The following claims specify the scope of the invention. Note that some aspects of the best mode may not fall within the scope of the invention as specified by the claims. Thus, those skilled in the art will appreciate variations from the best mode that fall within the scope of the invention. Those skilled in the art will appreciate that the features described below can be combined in various ways to form multiple variations of the invention. As a result, the invention is not limited to the specific examples described below, but only by the claims and their equivalents.

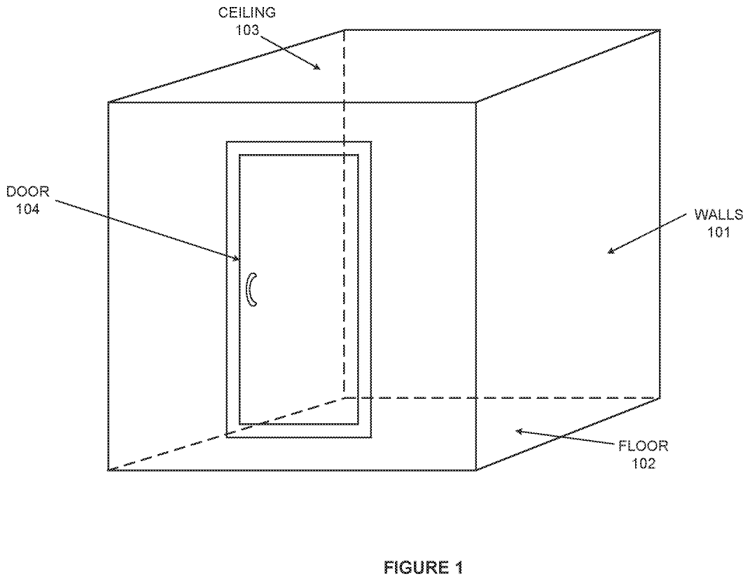

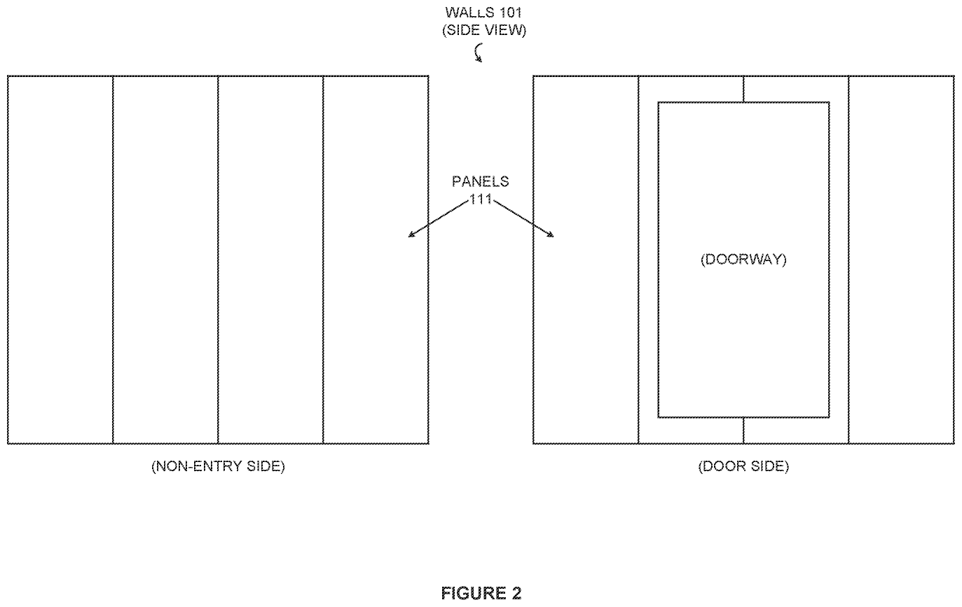

FIG. 1 illustrates modular magnetically shieled room 100. Magnetically shielded room 100 is a structure that blocks external electric and magnetic fields from entering the interior of room 100. The interior of room 100 may be used for magnetic and electric sensing technologies like Magnetoencephalography (MEG), Electroencephalography (EEG), Magnetoencephalography (MEG), Magnetocardiography (MCG), Magnetogastrography (MGG), Magnetomyography (MMG), and the like. For example, an MEG system may be placed within room 100 to measure magnetic fields generated by electric currents within a patient's brain to image the neuronal activity of the patient. Magnetically shielded room 100 comprises walls 101, floor 102, and ceiling 103. One of walls 101 comprises door 104 to provide an entryway to room 100. Although not illustrated in FIG. 1 for sake of clarity, walls 101, floor 102, and ceiling 103 comprise panels 111, corner brackets 112, outer frame 121, inner lattice 122, interior mu-metal layer 130, exterior mu-metal layer 140, exterior frame 151, and interior frame 152. These elements are illustrated in more detail in FIGS. 2-13. Although room 100 is illustrated as a cube shaped enclosure with four walls, the shape and number of walls of room 100 may differ in other examples. Likewise, the components that compose room 100 may differ or additional components may be present in other examples.

Various examples of electromagnetic shielding operations and configurations are described herein. In some examples, walls 101, floor 102, and ceiling 103 comprise an electrically conductive central layer and mu-metal. The electrically conductive layer forms the main structural element of room 100. For example, walls 101, floor 102, and ceiling 103 may each comprise four electrically conductive panels that comprise the load-bearing elements of room 100. The electrically conductive layer of walls 101, floor 102, and ceiling 103 forms a Faraday cage that shields the interior of room 100 from varying electromagnetic radiation (e.g., radio frequency interference). The electrically conductive layer may comprise any conductive material that has an electrically conductive surface. For example, the conductive layer may comprise coated aluminum, copper, brass, or another electrically conductive material with sufficient strength to support room 100. When the conductive layer comprises coated aluminum, the coating may comprise Alodine, chromate, tin, copper, and the like. It should be appreciated that the sufficient strength depends requirement depends in part on the size and shape of room 100 and may vary in different examples. For example, while gold may be a sufficiently conductive material, it may lack the strength to support the weight of room 100. When the electrically conductive layer of room 100 is exposed to an external electromagnetic field, the surface charge of the layer distributes based on the direction of the external field. The resulting charge distribution creates an opposing electromagnetic field that cancels the effects of the external electromagnetic field within room 100.

Mu-metal is a type of material that deflects magnetic fields. The mu-metal of room 100 is mounted to the surfaces of the electrically conductive layer of walls 101, floor 102, and ceiling 103. For example, the mu-metal may be mounted to the inner and/or outer surface of the electrically conductive layer. The mu-metal shields the interior of room 100 from magnetic fields. It should be appreciated that Faraday cages ineffectively block stable or slowly varying magnetic fields (e.g., the earth's magnetic field). As such, mounting the mu-metal to the electrically conductive layer allows room 100 to block both varying electromagnetic fields like radio frequency interference and stable or slowly varying magnetic fields like the earth's magnetic field. Mu-metal comprises a nickel alloy with high magnetic permeability. Mu-metals typically have a relative permeability between 80,000 and 100,000, however these values are exemplary and may differ in other examples. Exemplary mu-metal alloy compositions include nickel, iron, copper, and chromium/molybdenum alloys (e.g., 77% nickel, 16% iron, 5% copper, and 2% chromium or molybdenum) and nickel, molybdenum, silicon, and iron alloys (e.g., 80% nickel, 5% molybdenum, 12-15% iron, and trace amounts of silicon).

The high permeability of mu-metal provides a low reluctance path for magnetic flux. Magnetic flux describes the influence of a magnetic field over a given area. Magnetic reluctance describes a material's opposition to magnetic flux. Magnetic reluctance is analogous to electrical resistance in electric circuits. The low-reluctance of the mu-metal causes the path of magnetic field lines to flow around the mu-metal sheets thereby shielding the interior of room 100 from external magnetic fields. Although room 100 is described above as comprising mu-metal, other materials with similar relative permeability (e.g., between 80,000 and 100,000) may be mounted to the electrically conductive layer of walls 101, floor 102, and ceiling 103 to shield the interior of room 100 from external magnetic fields.

Door 104 allows people and equipment to enter room 100. Similar to walls 101, floor 102, and ceiling 103, door 104 comprises an electrically conductive layer and mu-metal to block electromagnetic fields from entering room 100. For example, door 104 may comprise a copper coated aluminum door with mu-metal sheets mounted to the surface. When closed, the electrically conductive layer of door 104 electrically couples with the electrically conductive layer of walls 101 to shield the interior of room 100 from varying electromagnetic fields. When closed, the mu-metal of door 104 couples with the mu-metal of walls 101 to shield the interior of room 100 from stable or slowly varying magnetic fields.

Advantageously, modular magnetically shielded room 100 effectively shields its internal volume from background electromagnetic noise. Moreover, the modularity and size of room 100 allows for efficient and cheap construction within existing structures.

FIG. 2 illustrates an example of walls 101 of magnetically shielded room 100. The left-hand side of FIG. 2 illustrates the non-entry ones of walls 101 while the right-hand side of FIG. 2 illustrates the wall that mounts door 104. Walls 101 comprise panels 111. In this example, each of walls 101 comprises four of panels 111, however the number of panels used to build walls 101, floor 102, and ceiling 103 may differ in other examples. Panels 111 comprise an electrically conductive material (e.g., coated aluminum) and form the electrically conductive layer of room 100. The central two of panels 111 of the door side one of walls 101 are “C” shaped. The “C” shaped ones of panels 111 are oriented in opposing directions to mount door 104. Floor 102 and ceiling 103 comprise a similar (or the same) construction as the non-entry ones of walls 101. For example, floor 102 and ceiling 103 may each comprise four of panels 111. As such, when walls 101, floor 102, and ceiling 103 are arranged to from magnetically shielded room 100, room 100 comprises a total of 24 panels, two of which being “C” shaped to mount door 104. In should be appreciated that since each of walls 101, floor 102, and ceiling 103 comprise a set of panels 101, the shape and size of room 100 may vary. For example, one or more of walls 101 may instead comprise eight of panels 111 to increase the volume of room 100. The panelized construction provides the modularity of room 100 allowing room 100 to take on different shapes for different implementations and environments.

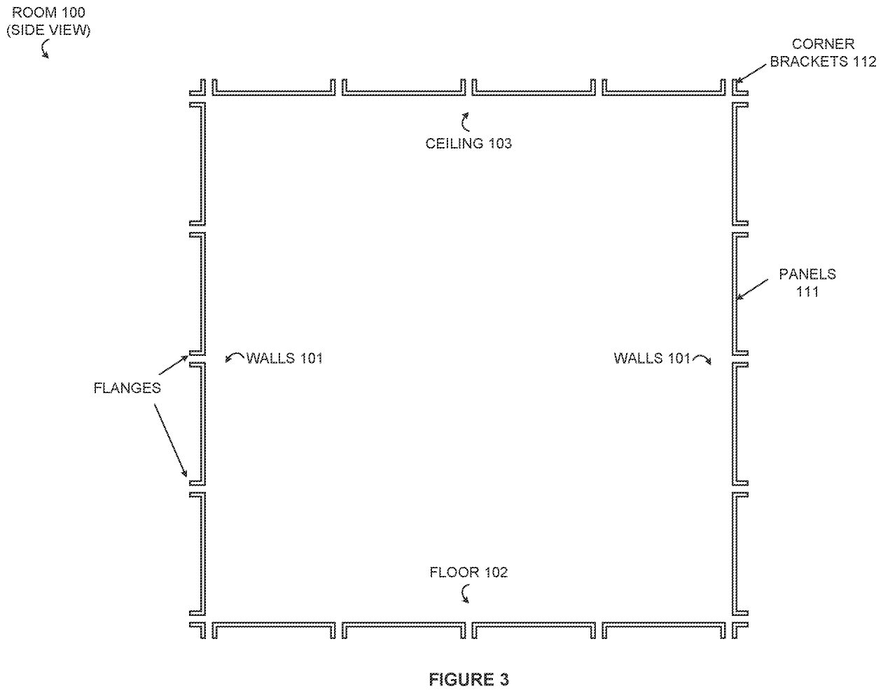

FIGS. 3-13 illustrate various views of modular magnetically shielded room 100 to illustrate the various orientations, compositions, constructions, layers, and physical interactions of the components that compose room 100. It should be appreciated that these views are exemplary and may differ in other examples. In some examples, FIGS. 3-13 may be representative of a set of state diagrams that illustrate a method of manufacturing room 100. Now referring to FIG. 3.

FIG. 3 illustrates a side view of room 100. The rear and entry ones of walls 101 are omitted for clarity. In some examples, walls 101, floor 102, and ceiling 103 comprise panels 111 and corner brackets 112 which form the main structural elements of room 100. Panels 111 and corner brackets 112 are illustrated as being separated for sake of clarity. Each of panels 111 comprises a flange that provides a mounting interface between adjacent ones of panels 111 and with corner brackets 112. Brackets 112 are positioned on the corners of room 100. Brackets 112 are “L” shaped and comprise a similar (or the same) length as panels 112. To mechanically couple panels 111 and brackets 112, the flanges of panels 111 and brackets 112 comprise a set of evenly spaced screw holes. To assemble the electrically conductive layer of room 100, panels 111 are screwed together to mechanically couple to one another to form walls 101, floor 102, and ceiling 103. Panels 111 are screwed to brackets 112 at the interfaces to between walls 101, floor 102, and ceiling 103 to couple walls 101, floor 102, and ceiling 103 to each other. Similar to panels 111, brackets 112 comprise an electrically conductive material. For example, brackets 112 may comprise Alodine coated aluminum. Since the surfaces of panels 111 and brackets 112 are electrically conductive, mechanically coupling panels 111 and brackets 112 also electrically couples panels 111 and brackets 112 to form the Faraday cage that shields the interior of room 100 from varying electromagnetic radiation.

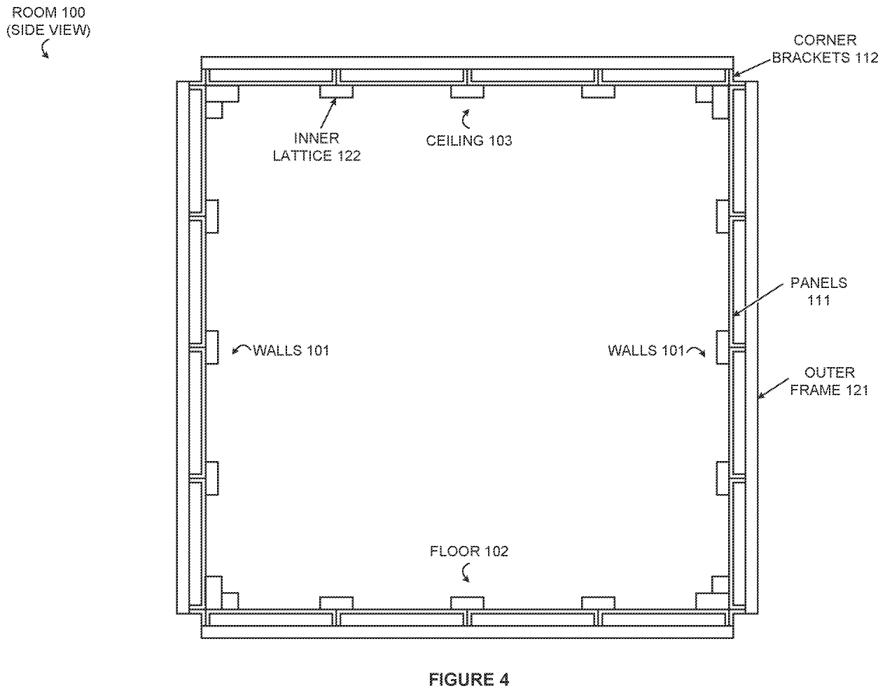

FIG. 4 further illustrates magnetically shielded room 100. Outer frame 121 is attached to the external surfaces of panels 111 and inner lattice 122 is attached to the interior surfaces of panels 111. Outer frame 121 and inner lattice 122 provide a mounting surface to attach mu-metal to the interior and exterior of room 100. Frame 121 and lattice 122 may comprise wood, rigid plastic, and/or another suitable mounting interface. The surfaces of panels 111 comprise evenly spaced surface screw ports. Inner lattice 122 is screwed to panels 111 through the surface ports to mount lattice 122. Outer frame 121 is screwed to panels 111 through the flange screw ports to mount outer frame 121. For example, wood blocks may be screwed to the flanges to provide the mounting surface for frame 121. In other examples, a construction adhesive (e.g., glue) may be used to mount frame 121 and lattice 122 to panels 111.

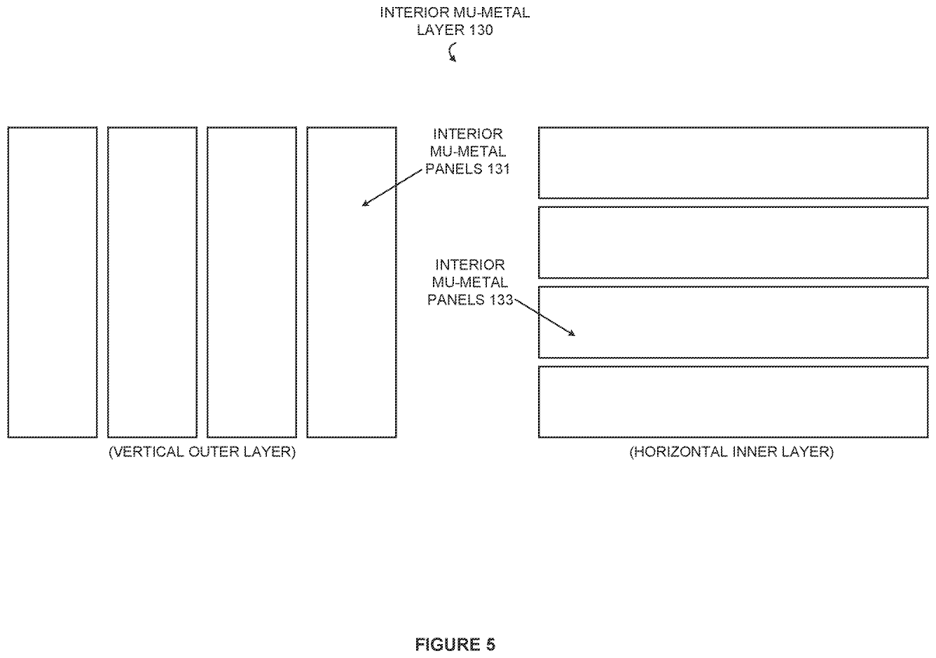

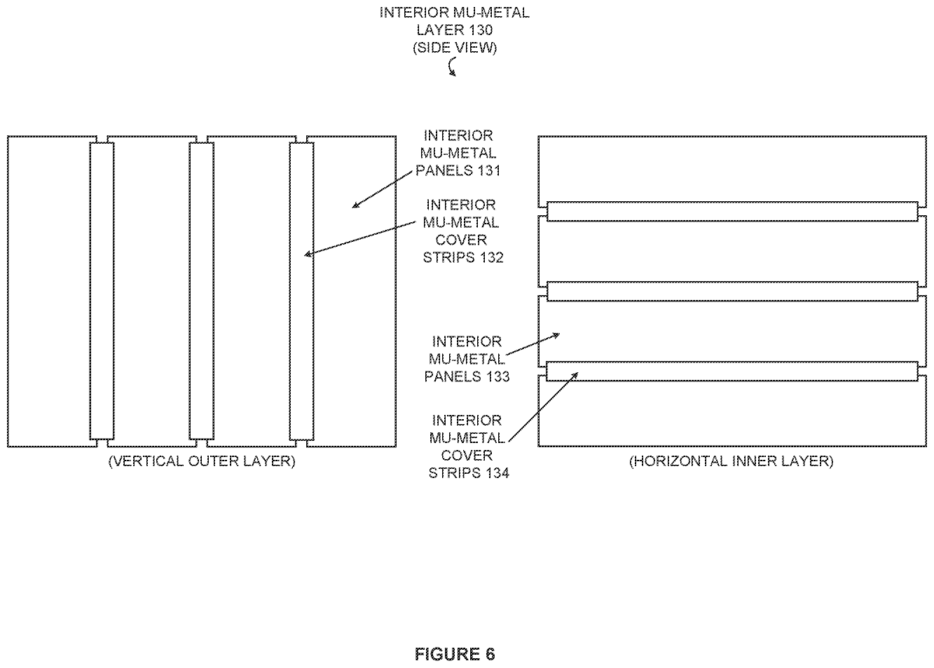

FIG. 5 illustrates interior mu-metal layer 130. Mu-metal layer 130 may be mounted to the interior of room 100 to shield room 100 from external magnetic fields. Mu-metal layer 130 comprises interior mu-metal panels 131 and 133 arranged in two layers. The vertical outer layer comprises mu-mental panels 131 arranged in a vertical orientation. The horizontal inner layer comprises mu-metal panels 133 arranged in a horizontal orientation. The horizontal and vertical layers are placed on top of one another to form layer 130. In this example, inner refers to being closer to the interior of room 100 while outer refers to being closer to the exterior of room 100, however both layers are mounted within room 100. As illustrated in FIG. 5, panels 131 and 133 are evenly spaced and comprise a similar surface area to walls 101, floor 102, and ceiling 103. FIG. 6 further illustrates interior mu-metal layer 130. Mu-metal layer 130 comprises interior mu-metal cover strips 132 and 134. The vertical outer layer comprises mu-mental cover strips 132 arranged in a vertical orientation. The horizontal inner layer comprises mu-metal cover strips 134 arranged in a horizontal orientation. Cover strips 132 and 134 bridge the gaps between mu-metal panels 131 and 133. Panels 131, cover strips 132, panels 133, and 134 comprise screw ports to mount interior mu-metal layer 130 to lattice 122. In other examples, interior mu-metal layer 130 instead comprises a single layer of mu-metal panels. In such example, either panels 131 and cover strips 132 or panels 133 and cover strips 134 are omitted.

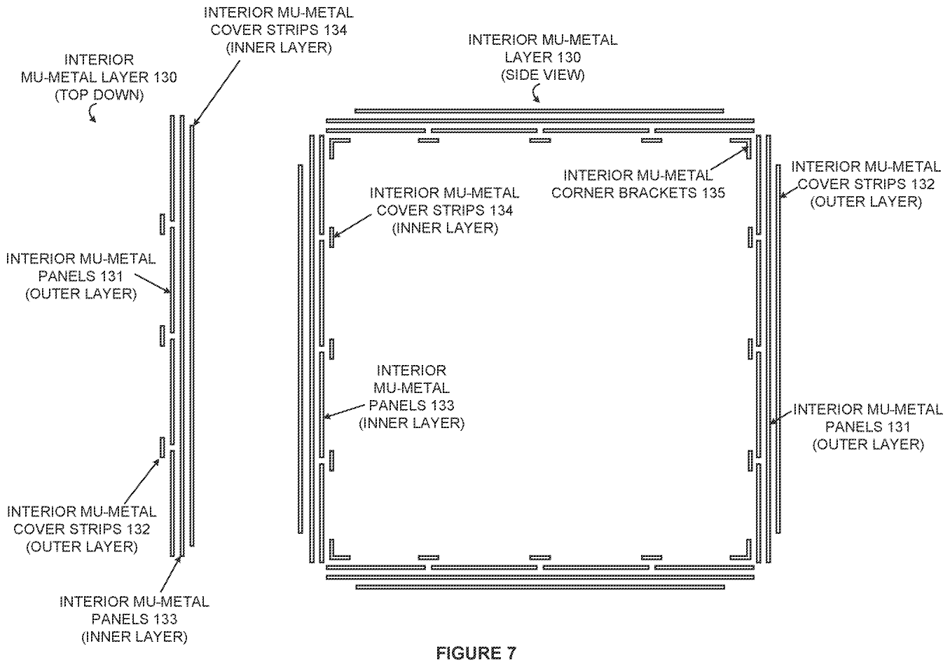

FIG. 7 further illustrates interior mu-metal layer 130 from a side view and a top-down view. In the top-down view, vertically aligned mu-metal cover strips 132 are positioned on the outer side of layer 130 while horizontally aligned mu-metal cover strips 134 are positioned on the inner side of layer 130. Cover strips 132 and 134 sandwich vertically aligned panels 131 and horizontally aligned panels 133. The side view of layer 130 illustrates the arrangement of layer 130 within room 100. Interior mu-metal layer 130 comprises interior mu-metal brackets 135 to couple adjacent ones of panels 131 and 133 mounted to walls 101, floor 102, and ceiling 103.

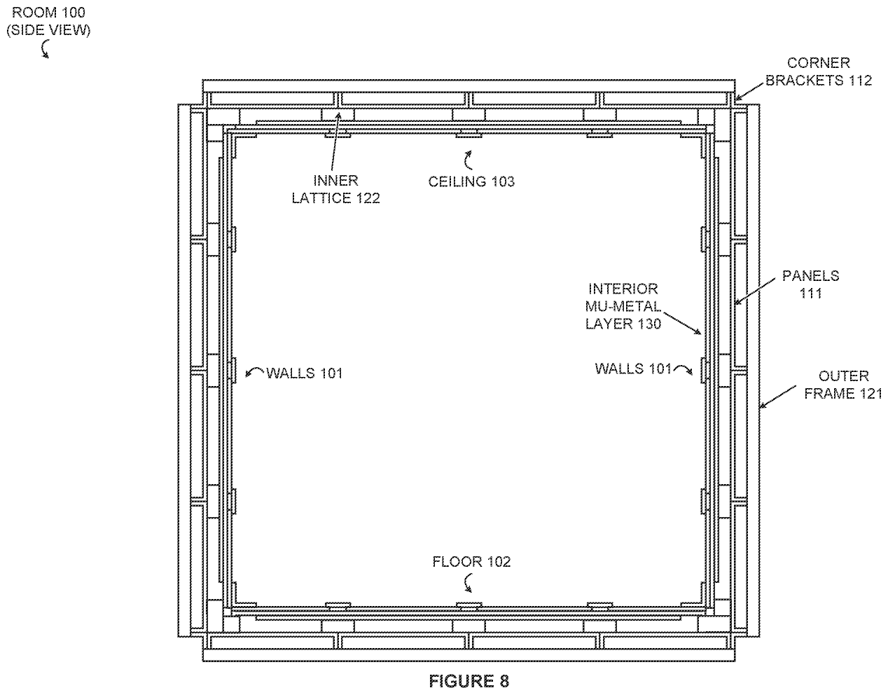

FIG. 8 further illustrates room 100 in a side view with interior mu-metal layer 130 mounted to the interior surfaces of walls 101, floor 102, and ceiling 103. Interior mu-metal layer 130 is mounted to panels 111 via inner lattice 122. To mount layer 130 to room 100, layer 130 is screwed to inner lattice 122 to mount layer 130 to panels 111. In other examples, layer 130 may be attached to lattice 122 using an adhesive (e.g., glue), hook-and-loop fasteners, or another type of binding system. Although not illustrated, inner lattice 122 extends to the inner surfaces of the rear and entry ones of walls 101. As such, interior mu-metal layer 130 encloses the interior of room 100. This enclosure shields the interior of room 100 from external magnetic fields.

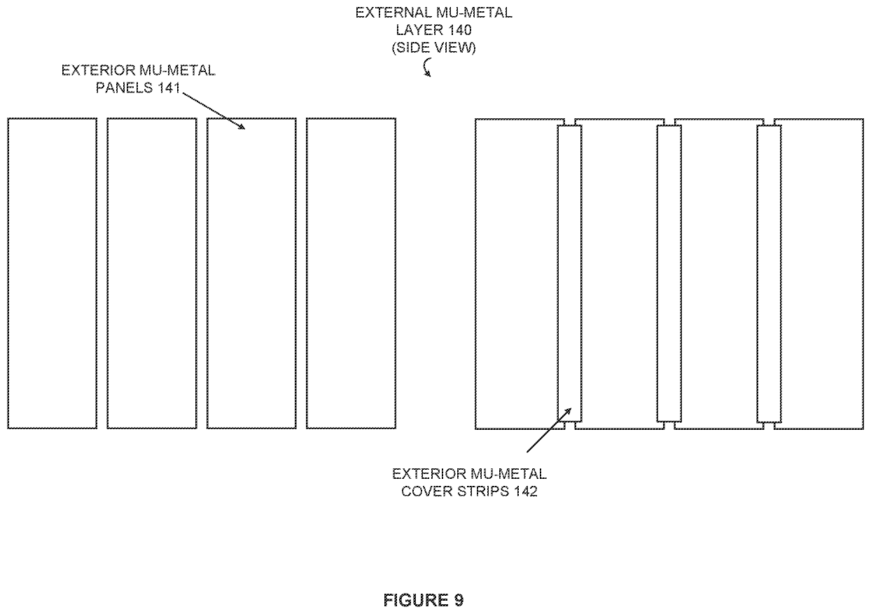

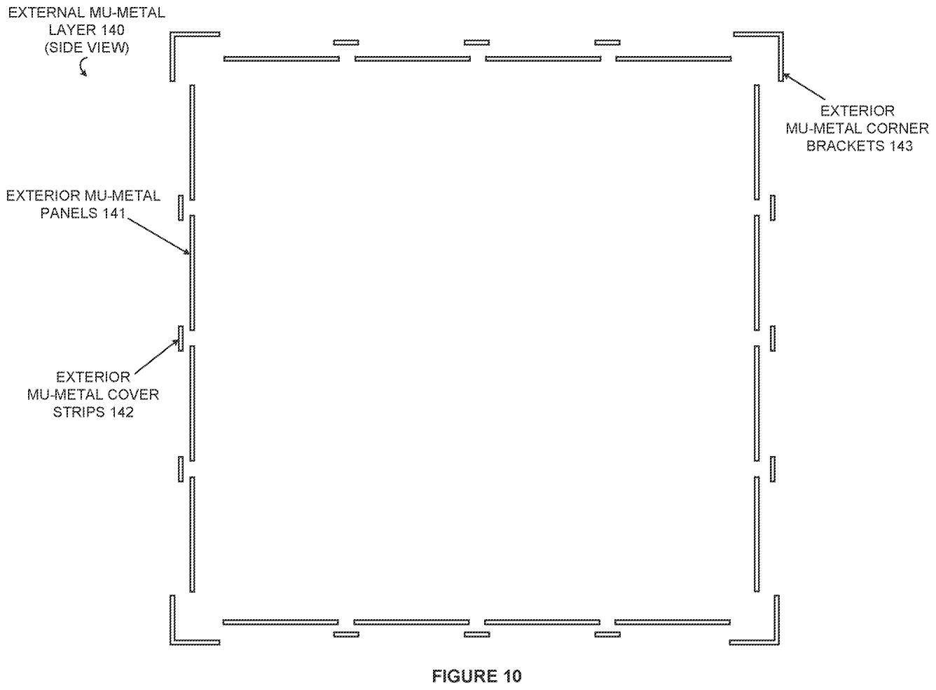

FIG. 9 illustrates exterior mu-metal layer 140. Mu-metal layer 140 may be mounted to the exterior of room 100 to shield room 100 from external magnetic fields. Mu-metal layer 140 comprises exterior mu-metal panels 141 and exterior mu-metal cover strips 142. In contrast to interior layer 130, exterior layer 140 comprises a single layer of mu-metal panels. As illustrated in FIG. 9, panels 141 are evenly spaced and comprise a similar surface area to walls 101, floor 102, and ceiling 103. Cover strips 142 bridge the gaps between mu-metal panels 141. Cover strips 142 and comprise screw ports to mount exterior mu-metal layer 130 to frame 121. Since layer 140 comprises a single layer of panels 141, panels 141 are not required to have screw ports to mount to the exterior of room 100. FIG. 10 illustrates a side view of layer 140. The side view of layer 140 illustrates the arrangement of layer 140 mounted to the exterior of room 100. Exterior mu-metal layer 140 comprises exterior mu-metal brackets 143 to couple adjacent ones of panels 141 mounted to walls 101, floor 102, and ceiling 103. In other examples, layer 140 may comprise a multi-layer construction similar to interior mu-metal layer 130.

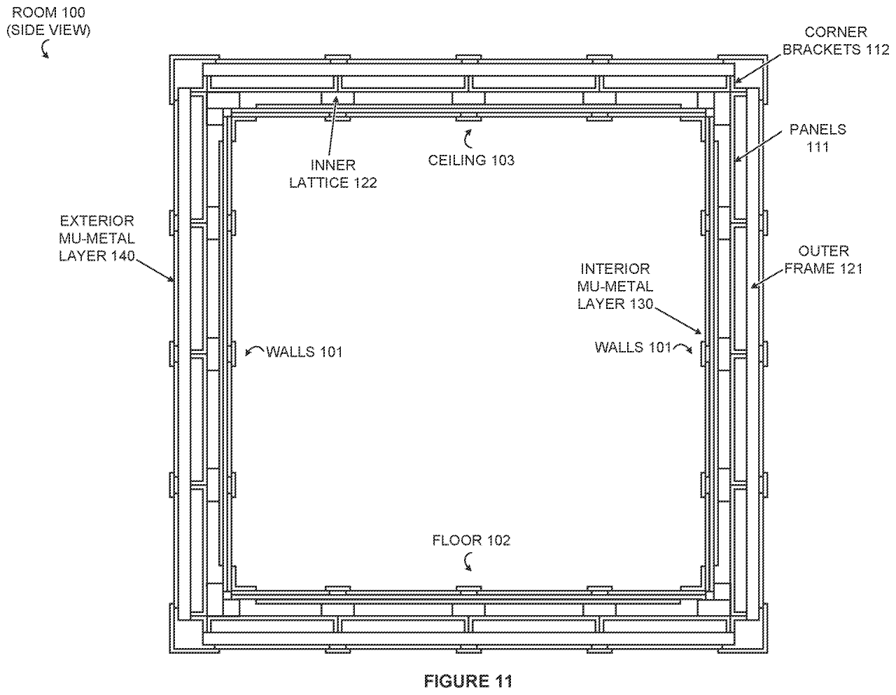

FIG. 11 further illustrates room 100 in a side view with exterior mu-metal layer 140 mounted to the outer surfaces of room 100. To mount layer 140 to room 100, exterior mu-metal layer 140 is screwed to outer frame 121 to mount layer 140 to panels 111. In other examples, layer 140 may instead attach to frame 121 using an adhesive, hook-and-loop fasteners, or some other mounting system. Although not illustrated, frame 121 extends to the outer surfaces of the rear and entry ones of walls 101. Exterior mu-metal layer 140 is also mounted to panels 111 of the rear and entry ones of walls 101 via frame 121. As such, exterior mu-metal layer 140 encloses the exterior of room 100. This enclosure further shields the interior of room 100 from external magnetic fields in addition to the shielding provided by layer 130.

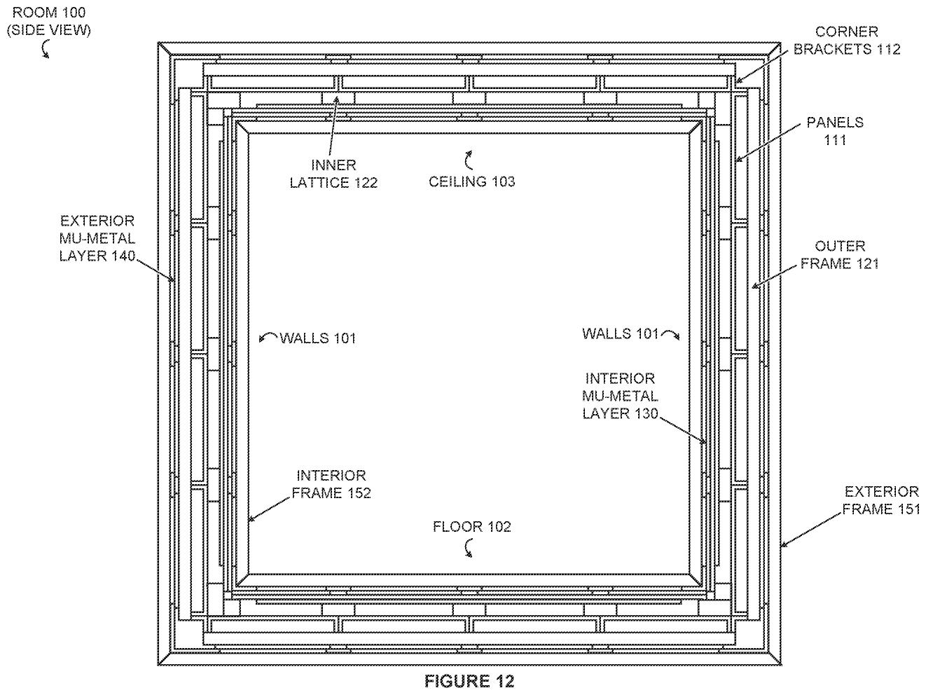

FIG. 12 further illustrates room 100 in a top-down perspective. In this view, room 100 comprises exterior frame 151 and interior frame 152. Exterior frame 151 mounts to the outer surface of exterior mu-metal layer 140. Interior frame 152 mounts to the internals surface of layer 130. To attach frames 151 and 152 to room 100 and secure mu-metal layers 130 and 140, screws are driven through exterior frame 151 and interior frame 152, threw the screw ports in mu-metal layers 130 and 140, and into frame 121 and lattice 122 to bind the mu-metal layers to panels 111.

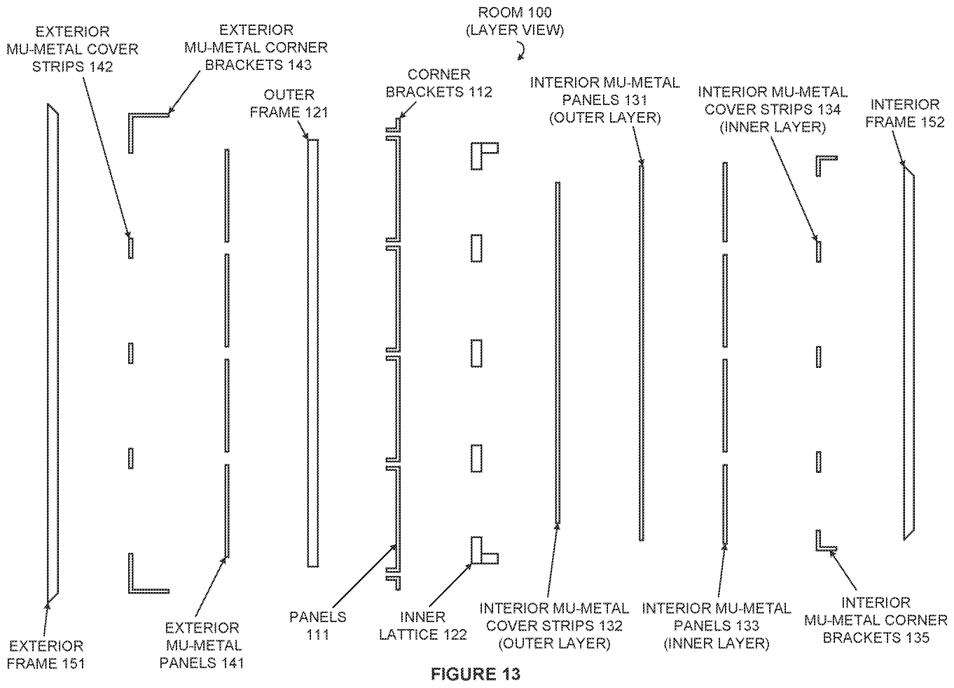

FIG. 13 illustrates a layered view of room 100. The left-hand side of FIG. 13 represents the outermost layer while the right-hand side of FIG. 13 represents the inner-most layer. Proceeding from outside to inside, room 100 comprise exterior frame 151, exterior mu-metal panels and brackets 141 and 143, outer frame 121, panels 111 and corner brackets 112, inner lattice 122, vertical cover strips 132, vertical mu-metal panels 131, horizontal mu-metal panels 133, horizontal cover strips 134 and brackets 135, and interior frame 152. While the above examples are given in the context of room 100 comprising two mu-metal layers, room 100 may instead comprise a single mu-metal layer construction. For example, room 100 may comprise one interior mu-metal layer or one exterior mu-metal layer. It should be appreciated that the layered view of room 100 illustrated in FIG. 13 is exemplary and that the number, type, and arrangement of the layers may differ in other examples.

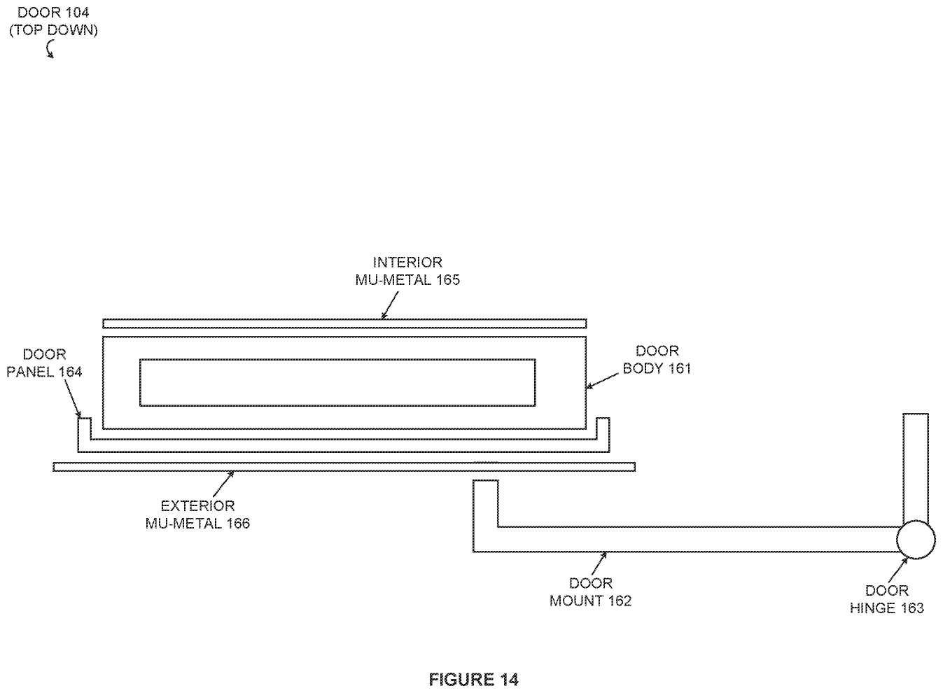

FIG. 14 illustrates door 104 from a top-down perspective. In some examples, door 104 comprises door body 161, door mount 162, door hinge 163, door panel 164, interior mu-metal 165, and exterior mu-metal 166. Door body 161 forms the main structure of door 104 and may comprise wood, plastic, and the like. Door body 161 is rectangular shaped and sized to fit the doorway formed by the “C” shaped ones of panels 111 of the door side one of walls 101. Door panel 164 is mounted to the exterior facing side of door body 161. Door panel 164 comprises an electrically conductive material like coated aluminum that, when closed, electrically couples to panels 111. Door body 161 is mounted to room 100 via door mount 162 and door hinge 163. Mount 162 couples to door panel 164 to attach door 104 to room 100. Interior mu-metal 165 is mounted to the inner surface of door body 161 and exterior mu-metal 166 is mounted to the exterior surface of door panel 164. When closed, interior mu-metal 165 contacts interior mu-metal layer 130 while exterior mu-metal 166 contacts exterior mu-metal layer 140.

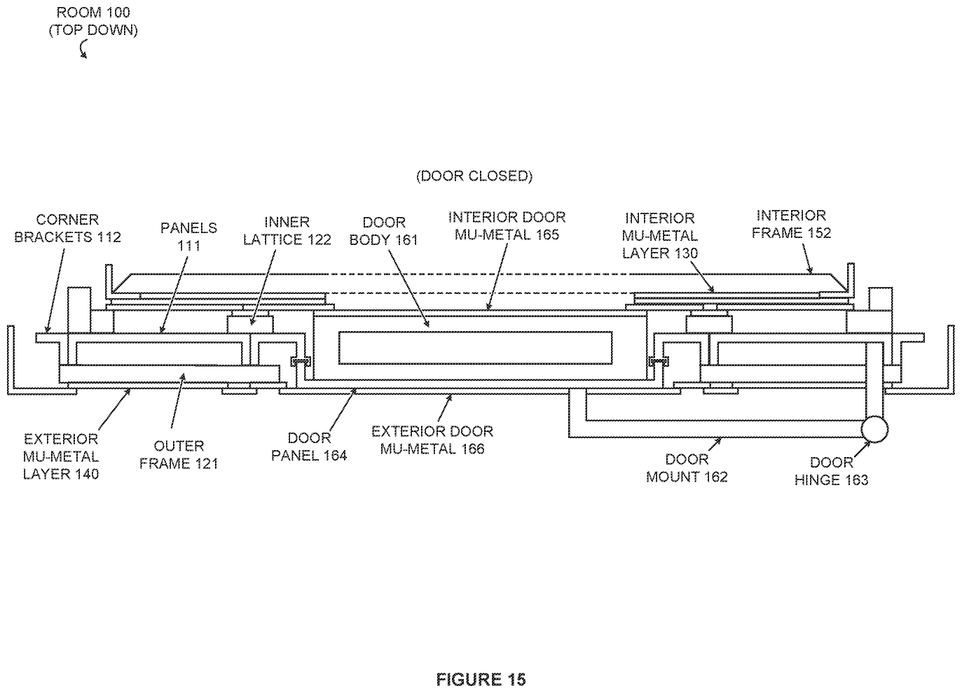

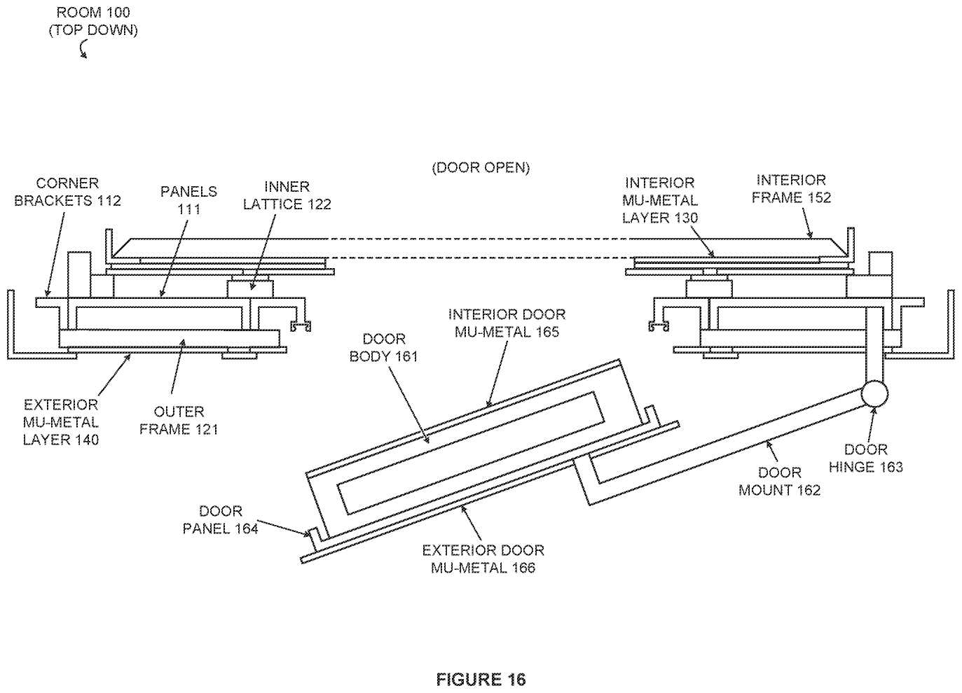

FIG. 15 illustrates room 100 in a top-down perspective to illustrate the interaction between door 104 and the door side one of walls 101 when closed. Door 104 attaches to panels 111 via door mount 162 and hinge 163. Mount 162 may use screws, be welded, or utilize another attachment method to attach door 104 to panels 111. In the closed position, door panel 164 contacts panels 111 of walls 101. As illustrated in FIG. 15, two of panels 111 comprise female sockets compatible with door panel 164. The flanges of door panel 164 insert into the female sockets to couple door panel 164 to the two of panels 111. The female sockets may comprise electrically conductive compression elements to secure door panel 164 when inserted into the female sockets. The compression elements may comprise spring loaded contacts or other types of electrically conductive compression elements. The compression elements squeeze door panel 164 to inhibit door 104 from moving when in the closed position. Since the surfaces of door panel 164 and panels 111 are electrically conductive, closing door 104 electrically couples door 104 to walls 101. In the closed position, interior mu-metal 165 contacts interior mu-metal layer 130 and exterior mu-metal 166 contacts exterior mu-metal layer 140. FIG. 16 illustrates room 100 in a top-down perspective to illustrate the interaction between door 104 and the door side one of walls 101 when open. In the open position, door panel 164 does not contact panels 111 and is not electrically coupled to panels 111. In the open position, interior mu-metal 165 does not contact interior mu-metal layer 130 and exterior mu-metal 166 does not contact exterior mu-metal layer 166.

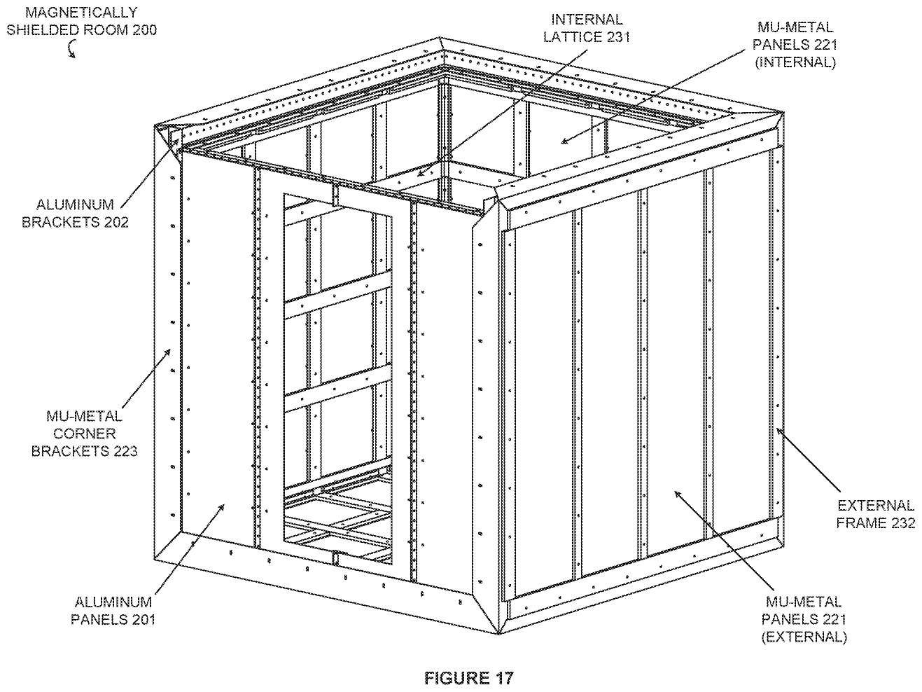

FIG. 17 illustrates modular magnetically shielded room 200. Room 200 comprises an example of room 100 however room 100 may differ. Although portions of room 200 are omitted from FIG. 17 for clarity, room 200 comprises aluminum panels 201, aluminum corner brackets 202, inner lattice 211, outer frame 212, mu-metal panels 221, mu-metal cover strips 222, mu-metal corner brackets 223, internal lattice 231, external frame 232, feet 241, and waveguide 251. The ceiling and door of room 200 are omitted to illustrate room 200's interior. In other examples, room 200 may comprise different or additional components.

In some examples, modular magnetically shielded room 200 comprises a cube-shaped room. The exterior dimensions of room 200 measure roughly 2.6 m×2.6 m×2.6 m and while the interior dimensions of room 200 measure roughly 2.5 m×2.5 m×2.5 m. Room 200 comprises three layers: an external mu-metal layer, a conductive central aluminum layer, and an internal mu-metal layer. The mu-metal layers are formed by mu-metal panels 221, mu-metal cover strips 222, and mu-metal corner brackets 223 while the central aluminum layer is formed by aluminum panels 201 and aluminum corner brackets 202. The conductive aluminum layer comprises the primary structural element of room 200.

Panels 201 comprise aluminum plates with edge flanges to form structural ribs causing panels to resemble the lid to a shoebox. Four of panels 201 match up side-by-side to construct each wall, the ceiling, and floor of room 200. Aluminum panels 201 that form the door-side wall of room 200 are visible in the view illustrated by FIG. 14, however these ones of panels 201 are typically covered by mu-metal panels 221. Panels 201 may be screwed, bolted, or otherwise coupled to each other through their flanges to attach to one another and structurally hold room 200 together when assembled. When assembled, room 200 comprises 24 of aluminum panels 201 creating the structural center layer between the inner and outer mu-metal layers. Two of panels 201 comprise “C” shaped panels positioned in opposing directions to form the doorway of room 200. Aluminum brackets 202 comprise “L” brackets that mechanically couple each of the walls, floor, and ceiling to each other at their respective interfaces. Brackets 202 may be placed against the flanges of panels 201 and screwed, bolted, or otherwise coupled to the flanges to assemble the walls, floor, and ceiling of room 200.

The interior mu-metal layer is mounted to the aluminum layer of the magnetically shielded room 200. This layer of mu-metal comprises a two-layer lattice pattern of mu-metal panels 221. The two-layer lattice pattern comprises a vertically oriented outer layer and a horizontally oriented inner layer. Mu-metal panels 221 that form the two-layer lattice are sandwiched together by mu-metal cover strips 222 on both sides. The view of mu-metal cover strips 222 in FIG. 17 is obstructed by internal lattice 231 and external frame 232. Each internal side of room 200 comprises eight of mu-metal panels 221 and six of mu-metal cover strips 222. The external mu-metal layer comprises a single layer of mu-metal panels 221. Mu-metal cover strips 222 fill the gaps between panels 222 and allow wood cover strips to mount panels 221 to each wall. The external surface of each side or room 200 has four of mu-panels 221 and three of mu-metal cover strips 222.

Inner lattice 211 and outer frame 212 comprise wood to mount the mu-metal layers to the aluminum layer. The view of inner lattice 211 and outer frame 212 is obstructed in FIG. 17 by mu-metal panels 221. Inner lattice 211 and outer frame 212 for the mu-metal layers create spacing between the aluminum and the mu-metal layers. In the interior of room 200, the interior mu-metal lattice and cover strips have screw clearance holes to mount the panels to the inner lattice 211. On the outside, only the cover strips have screw holes which will frictionally pinch the mu-metal panels between outer frame 212 and external frame 232. Wood screws may be used for mounting on both mu-metal layers. Mu-metal corner brackets 223 couple the edges of the internal and external mu-metal layers. 12 of mu-metal corner brackets 223 go along each edge on the inside and outside mu-metal layers totaling 24 edge pieces. At the vertices where edges meet up, mu-metal corner brackets 223 are cut at a 45-degree angle in order to maintain relief from interference as well as minimize the open space in between mu-metal panels or perpendicular walls. The outer surface of the floor of room 200 comprises feet 241 to support room 200.

In some examples, room 200 comprises individually addressable coils mounted to the interior surfaces of the walls, floor, and ceiling. For example, the coils may be embedded into circuit boards and the circuit boards may be attached to internal lattice 231. When current is supplied to the coils, the coils generate a nulling electromagnetic field within room 200. The nulling field counteracts background magnetic fields that leak into room 200. The nulling further helps to shield the interior of room 200 from external magnetic fields.

In some examples, room 200 comprises a degaussing system. Degaussing (e.g., demagnetizing) is the process of decreasing or removing a remnant magnetic field. The degaussing system comprises a single cable that loops throughout the internal and external surfaces of room 200. The degaussing system may be attached to room 200 using conduit mounted to the internal and external wood frames of room 200. For example, the cable may track along the internal and external interfaces between the walls, floor, and ceiling of room 200. When activated, the degaussing system removes or otherwise reduces magnetism present in the internal and external mu-metal elements of room 200. For example, current may be passed through the cable of the degaussing system for a period of time (e.g., ten seconds) to degauss the mu-metal elements of room 200. Degaussing the mu-metal elements further helps to shield the interior of room 200 from magnetic fields.

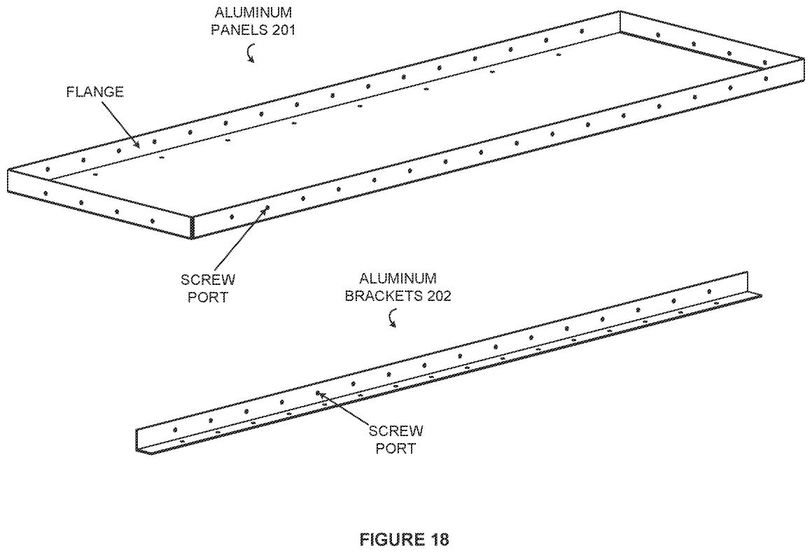

FIG. 18 illustrates aluminum panels 201 and cross brackets 202. Aluminum panels 201 comprise ¼″ thick 5052 aluminum plates with outer dimensions of 2.5 m×0.625 m. When screwed together, four of aluminum panels 201 forming one side of room 200 comprise a surface area of 2.5 m×2.5 m. On the long side of panels 201, the flanges comprise 40 evenly spaced screw ports that allow panels 201 to be bolted together to form the walls, floor, and ceiling of room 200. The holes comprise ¼″-20 screw clearance holes. The holes are evenly spaced at intervals of 62.5 mm. A similar spacing of 62.5 mm is used to space the holes on the short length of each of panels 201, in order to match up with the long length. The spacing allows each of panels 201 the ability to be mounted together no matter the orientation. The spacing and/or number of screw ports in each of panels 201 can vary. In some examples, the spacing between the screw ports depends in part on the size of the panels. For example, a panel that is 0.625 m wide may comprise screw ports spaced every 62.5 mm implying a ten-to-one spacing-to-width ratio. Typically, the spacing between the screw ports is less than 20 times the thickness of the panel to ensure the connected panels make adequate electrical contact. When the spacing between the screw ports exceeds a spacing-to-thickness ratio threshold (e.g., greater than 20 times the thickness of the panel), the shielding factor of room 200 degrades.

Aluminum brackets 202 comprise “L” brackets. Brackets 202 comprise evenly spaced screw ports at intervals of 62.5 mm that align with the screw ports of panels 201. Brackets 202 are bolted to panels 201 at the interfaces of the walls, floor, and ceiling of room 200. A portion of brackets 202 comprise are for the vertical edges or room 200 and another portion of brackets 202 are for the horizontal edges of room 200. Room 200 comprises four vertical ones of brackets 202 and eight horizontal ones of brackets 202. The vertical ones of brackets 202 measure 2.7 m long, while the horizontal ones of brackets 202 measure 2.5 m long. Brackets 202 each comprise the same hole pattern as the flanges of panels 201 to match up with both the short and long lengths of aluminum panels 201. The flanges on brackets 202 components are 4 in long to provide the spacing for the interior and exterior mu-metal layers.

In should be appreciated that aluminum is electrically conductive. However, the oxide layer that forms on the surface of aluminum is an electrical insulator. The oxide layer on panels 201 and brackets 202 is removed and replaced with an electrically conductive surface coating. Exemplary surface coatings include Alodine, chromate, copper, tin, and the like. As such, when panels 201 and brackets 202 are mechanically coupled to one another, panels 201 and brackets 202 become electrically coupled. The electric coupling forms a Faraday cage to shield the interior of room 200 from electromagnetic radiation (e.g., radio frequency interference).

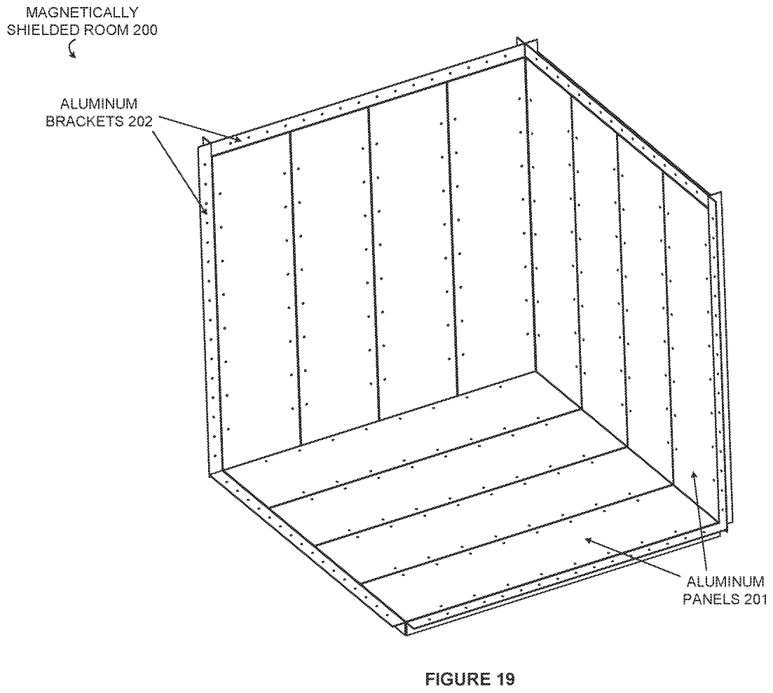

FIG. 19 illustrates a perspective view of the central aluminum layer of room 200. The ceiling, right-side wall, and entryway wall are omitted for sake of clarity. For each side of room 201, four of panels 201 are bolted together to form the floors, walls, and ceiling of room 200. Brackets 202 are attached to the exposed flanges of panels 201 to mechanically couple the surfaces of room 200 forming the central aluminum layer. In some examples, aluminum panels 201 comprise a single ground connection to earth ground. For example, a ground wire may be connected to one of aluminum panels 201 to ground the entire aluminum conductive structure. The single ground connection inhibits Electromagnetic Interference (EMI) from affecting electronics (e.g., magnetometers) operating within room 200.

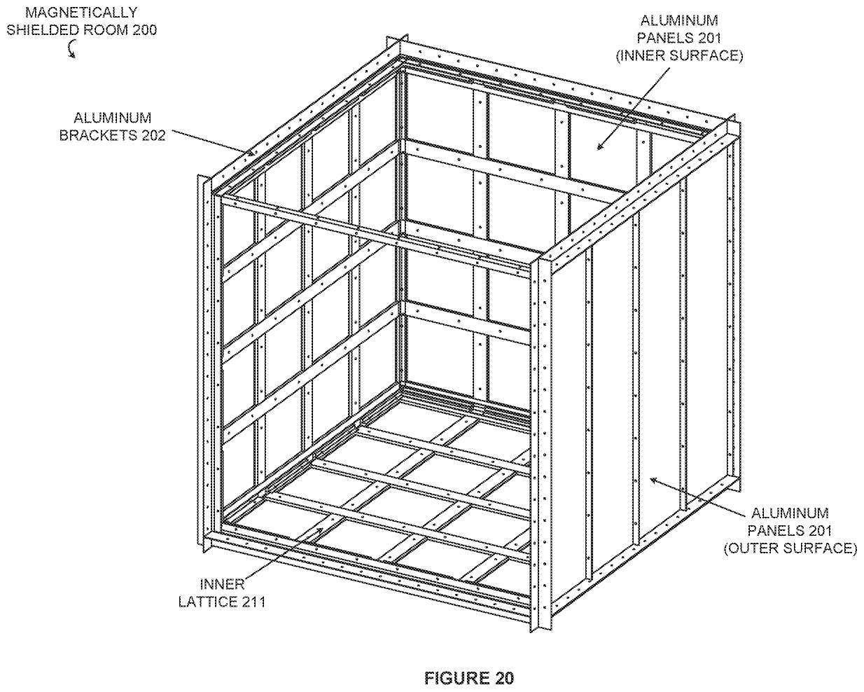

FIG. 20 further illustrates the central aluminum layer of room 200. Inner lattice 211 is screwed to panels 201 through the surface screw ports of panels 201. Inner lattice 211 comprises wood strapping to provide a mounting surface for the interior mu-metal layer. Although not illustrated, outer frame 212 is screwed to the flanges of panels 201. Outer frame 212 comprises wood strapping to provide a mounting surface for the exterior mu-metal layer.

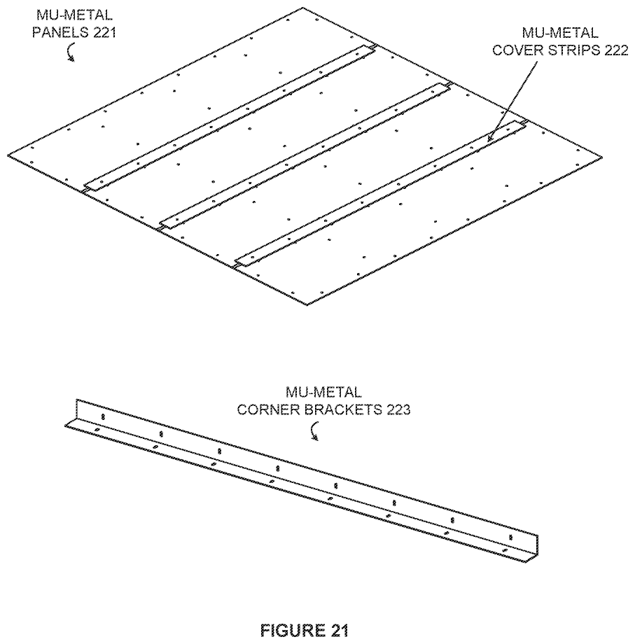

FIG. 21 illustrates mu-metal panels 221, mu-metal cover strips 222, mu-metal corner brackets 223. Panels 221 are evenly spaced and cover strips 222 bridge the gaps between the panels and allow wood cover strips to mount panels 221 to each wall. Mu-metal panels 221 and mu-metal cover strips 222 comprise screw ports to mount to inner lattice 211 and outer frame 212. The inner mu-metal layer comprises a two-layer lattice of panels 221 and cover strips 222. The two-layer lattice pattern comprises a vertically oriented outer layer and a horizontally oriented inner layer. For each interior side of room 200, the internal mu-metal layer comprises eight of mu-metal panels 221 and six of mu-metal cover strips 222. Internal ones of mu-metal panels 221 measure 0.8 mm thick and comprise a surface area of 2460×585 mm. Internal ones of cover strips 222 measure 0.8 mm thick and comprise a surface area of 2321×80 mm. Inner lattice 211 creates a spacing of 25.85 mm between the interior mu-metal layer and the aluminum layer of the magnetically shielded room 200.

The outer mu-metal layer comprises a single layer of panels 221 and strips 222. For each exterior side of room 200, the external mu-metal layer comprises 4 of mu-metal panels 221 and three of mu-metal cover strips 222. External ones of mu-metal panels 221 measure 1.5 mm thick and comprise a surface area of 2484×610 mm. External ones of mu-metal cover strips 222 measure 1.5 mm thick and comprise a surface area of 2420×80 mm. Mu-metal corner brackets 223 couple the edges of the internal and external mu-metal layers. The exterior mu-metal layer is spaced 221 are spaced at 107.95 mm from the aluminum layer. The interior and exterior mu-metal layers form surfaces with high magnetic permeability to deflect external magnetic fields thereby shielding the interior of room 200 from external magnetic fields.

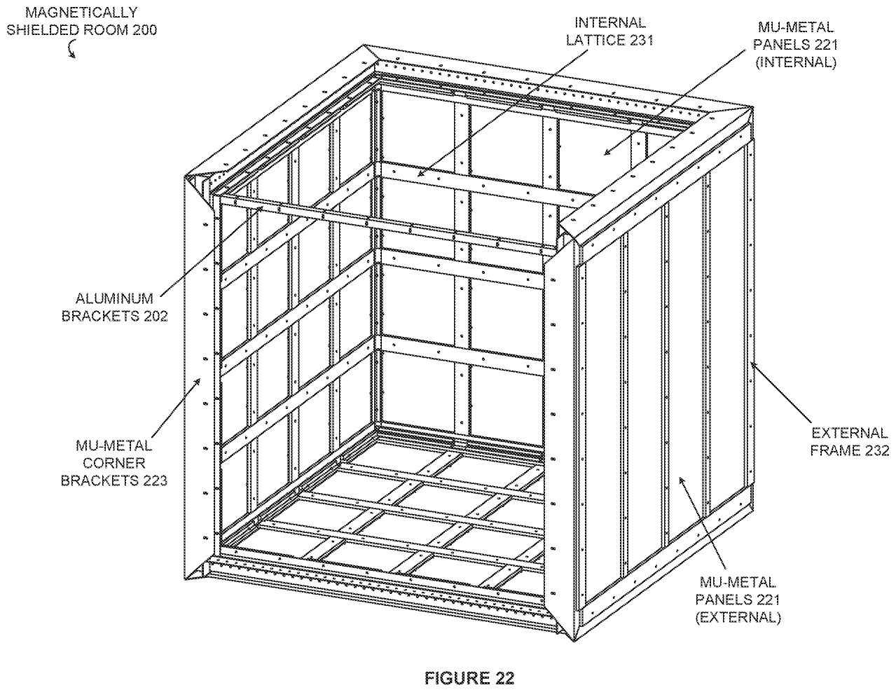

FIG. 22 illustrates a view of room 200 with the internal and external mu-metal layers mounted to the central aluminum layer by inner lattice 211 and outer frame 212. Internal lattice 231 is placed against the exposed surface of the inner mu-metal layer. Screws are driven through lattice 231, through the screw ports in mu-metal panels 221 and cover strips 223, and into inner lattice 211 to mount the inner mu-metal layer to the central aluminum layer. Similarly, external frame 232 is mounted to the exposed surface of the external mu-metal layer. Screws are driven through external frame 231, through the screw ports in cover strips 223, and into outer frame 212 to mount the outer mu-metal layer to the central aluminum layer.

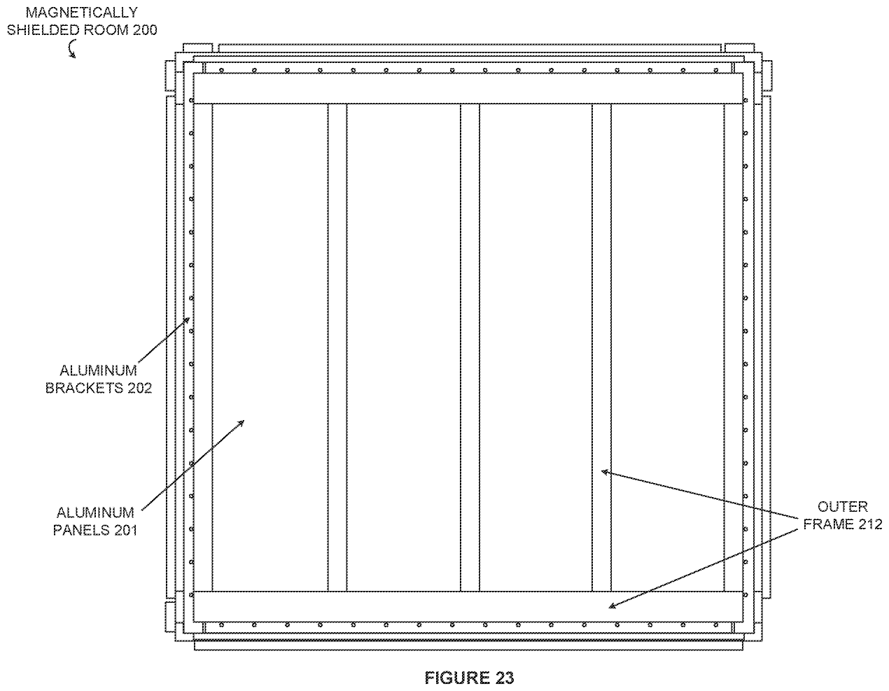

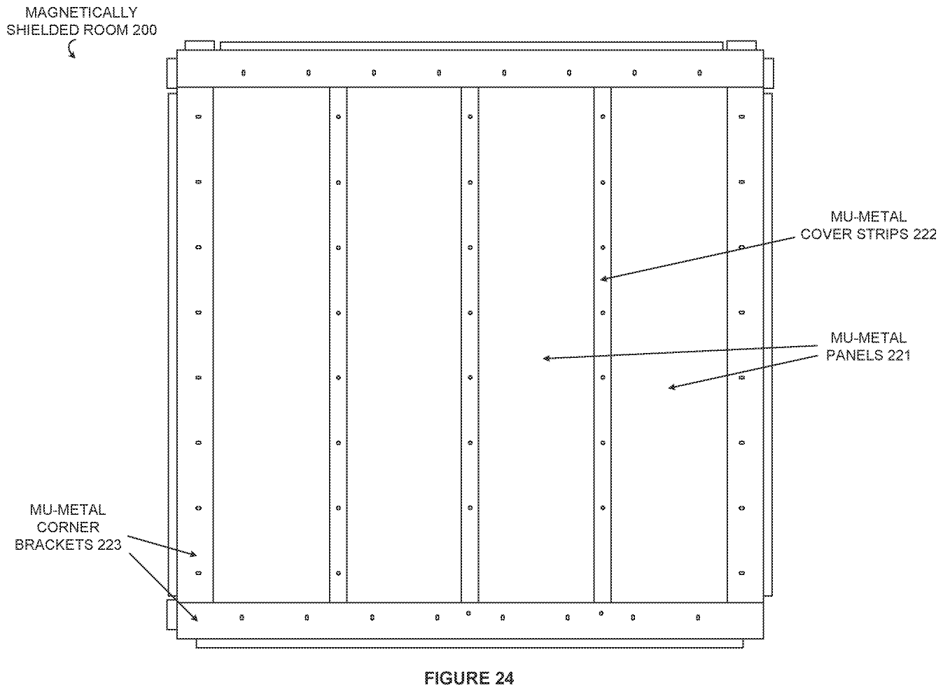

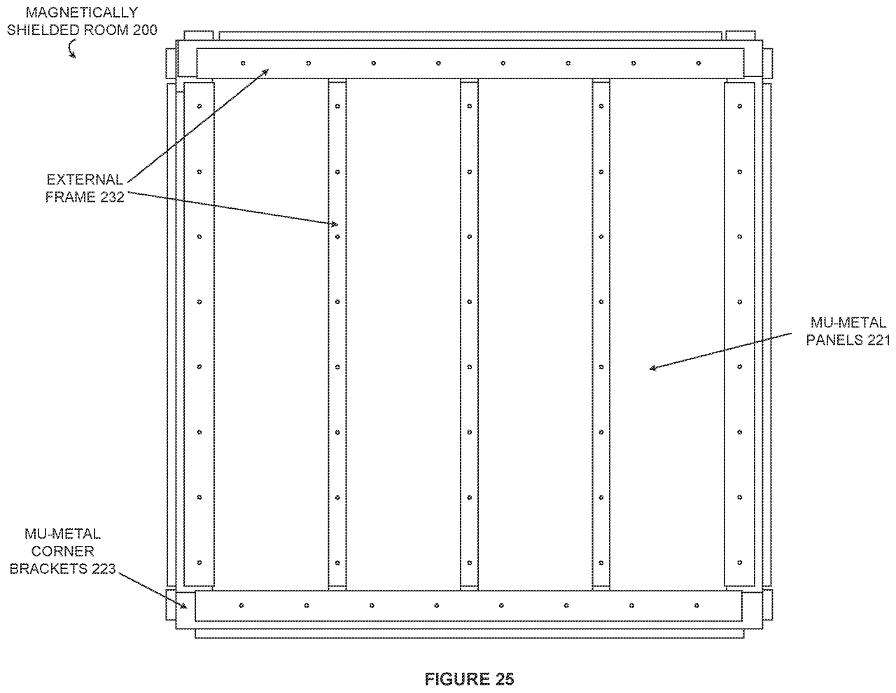

FIGS. 23-25 further illustrate views of room 200 to demonstrate the mounting process of the external mu-metal layer. Referring to FIG. 23, outer frame 212 is screwed to the flanges of panels 201. For example, wood blocks may be attached to the flanges to provide a mounting surface for frame 212. Frame 212 may then be screwed to the wood blocks to couple frame 212 to panels 201. Referring to FIG. 24, mu-metal panels 221, cover strips 222, and corner brackets 223 of the external mu-metal layer are placed against the frame. Referring to FIG. 25, external frame 232 is placed against the external mu-metal layer and screwed to outer frame 212 through the screw ports in cover strips 222 and corner brackets 223.

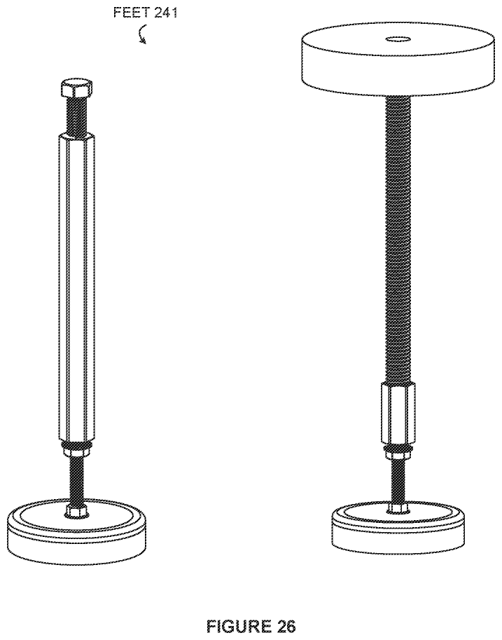

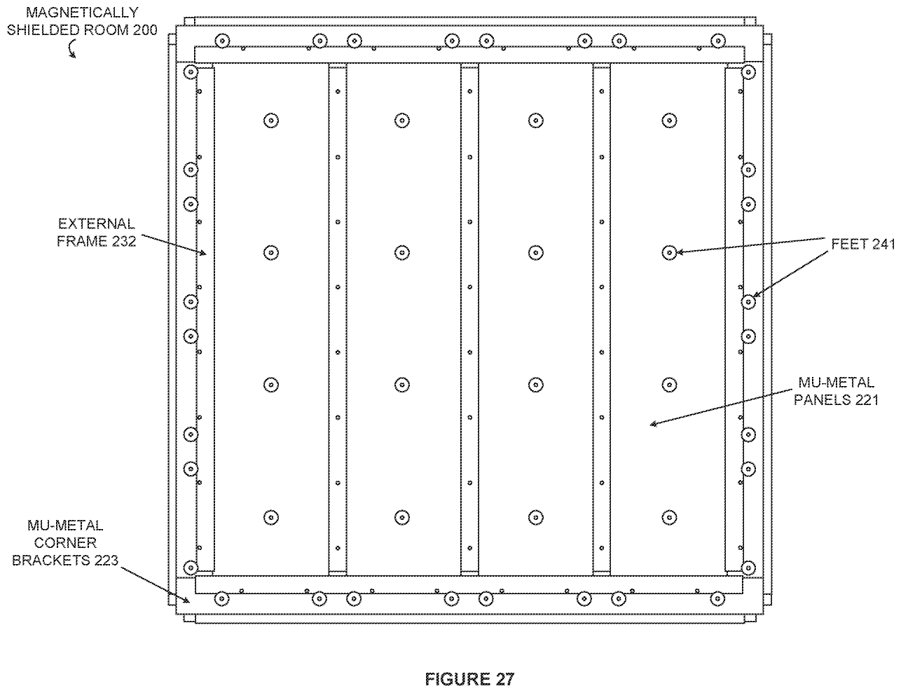

FIG. 26 illustrates support feet 241 for room 200. Feet 241 comprise ½″-20 threaded rods, nuts, washers, sorbothane levelers, and couplers. On each of feet 241, the coupler connects the threaded rod to the sorbothane damper foot, then further up the threaded rod, two sets of nuts and washers support aluminum panels 201 through the threaded holes cut into the bottom ones of panels 201. FIG. 27 illustrates the exterior surface of the floor of room 200. The four bottom corners on the exterior of room 200 comprise relief holes compatible for feet 241. Panels 201, brackets 202, and mu-metal corner brackets 223 also comprise relief holes compatible with feet 241. Feet 241 are attached to the external surface of the floor of room 201 at the relief holes. In total, 48 of feet 241 are attached to room 200 to support the weight of room 200 and provide damping from external disturbances.

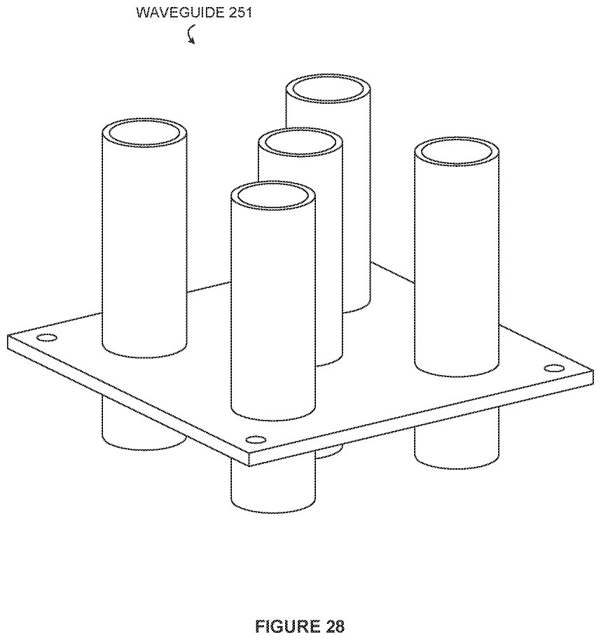

FIG. 28 illustrates waveguide 241. Waveguide 241 comprises an aluminum plate with five conduits. Waveguide 241 provides a pathway for signal, data, power, and ground links to enter room 200. For example, room 200 may house a MEG system to measure magnetic fields generated by neuronal activity in the human brain. The MEG system may use waveguide 241 to connect its signal, data, power, and ground links to a controller located outside of room 200. The aluminum plate comprises five holes that correspond to the conduits. The inner diameter of the conduit comprises 42 mm and outer diameter of the conduit comprises 48 mm.

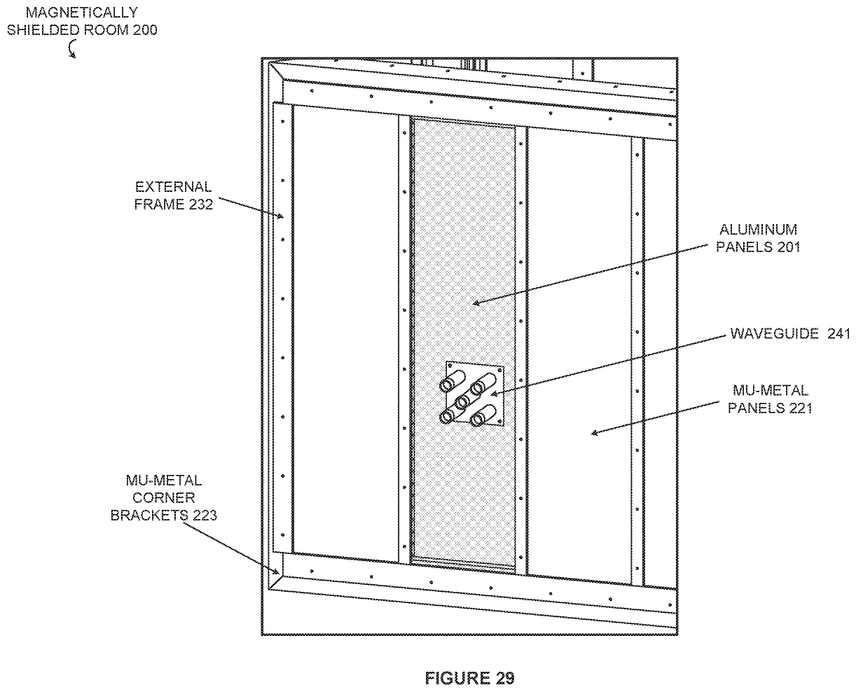

The cross-sectional area of waveguide 241 measures 6900 mm². Now referring to FIG. 29, waveguide 241 is positioned on one of panels 201. A hole that corresponds to the size of waveguide 241 is cut into the panel. Waveguide 241 is mounted to the panel at the hole. Although not illustrated, holes are cut into the internal and external mu-metal layers that correspond to the size of the conduits allowing the conduits to pass through each layer of room 200.

The illustrations of the embodiments described herein are intended to provide a general understanding of the structure of the various embodiments. While several implementations are described in connection with these illustrations of the embodiments, the disclosure is not limited to the implementations disclosed herein. On the contrary, the intent is to cover all alternatives, modifications, and equivalents. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Moreover, although specific embodiments have been illustrated and described herein, it should be appreciated that any subsequent arrangement designed to achieve the same or similar purpose may be substituted for the specific embodiments shown.

This disclosure is intended to cover any and all subsequent adaptations or variations of various embodiments. Combinations of the above embodiments, and other embodiments not specifically described herein, will be apparent to those of skill in the art upon reviewing the description. While, for purposes of simplicity of explanation, methods included herein may be in the form of a functional diagram, operational scenario or sequence, or flow diagram, and may be described as a series of acts, it is to be understood and appreciated that the methods are not limited by the order of acts, as some acts may, in accordance therewith, occur in a different order and/or concurrently with other acts from that shown and described herein. For example, those skilled in the art will understand and appreciate that a method could alternatively be represented as a series of interrelated states or events, such as in a state diagram. Moreover, not all acts illustrated in a methodology may be required for a novel implementation. Additionally, the illustrations are merely representational and may not be drawn to scale. Certain proportions within the illustrations may be exaggerated, while other proportions may be reduced. Accordingly, the disclosure and the figures are to be regarded as illustrative and not restrictive.

The various materials and manufacturing processes discussed herein are employed according to the descriptions above. However, it should be understood that the disclosures and enhancements herein are not limited to these materials and manufacturing processes, and can be applicable across a range of suitable materials and manufacturing processes. Thus, the descriptions and illustrations included herein depict specific implementations to teach those skilled in the art how to make and use the best options. For the purpose of teaching inventive principles, some conventional aspects have been simplified or omitted. Those skilled in the art will appreciate variations from these implementations that fall within the scope of this disclosure. Those skilled in the art will also appreciate that the features described above can be combined in various ways to form multiple implementations.

The above description and associated figures teach the best mode of the invention. The following claims specify the scope of the invention. Note that some aspects of the best mode may not fall within the scope of the invention as specified by the claims. Those skilled in the art will appreciate that the features described above can be combined in various ways to form multiple variations of the invention. Thus, the invention is not limited to the specific embodiments described above, but only by the following claims and their equivalents.

What is claimed is:

1. A modular magnetically shielded room to shield a magnetic field detection system from electromagnetic interference, the modular magnetically shielded room comprising:
walls, a floor, and a ceiling that enclose an interior volume;
the walls, the floor, and the ceiling each comprising electrically conductive panels, each of the electrically conductive panels comprising a flange to mechanically couple to adjacent ones of the electrically conductive panels, wherein mechanically coupling the electrically conductive panels to each other electrically couples the electrically conductive panels to each other;
electrically conductive brackets to mechanically couple to the flanges of the electrically conductive panels at interfaces between the walls, the floor, and the ceiling, wherein mechanically coupling the electrically conductive brackets to the flanges of the electrically conductive panels electrically couples the electrically conductive brackets to the electrically conductive panels;
internal mu-metal panels mounted to internal surfaces of the electrically conductive panels of the walls, the floor, and the ceiling; and
external mu-metal panels mounted to external surfaces of the electrically conductive panels of the walls, the floor, and the ceiling.

2. The modular magnetically shielded room of claim 1 further comprising an inner wood lattice; and wherein:
the inner wood lattice is mounted to the internal surfaces of the electrically conductive panels; and
the internal mu-metal panels are mechanically coupled to the internal wood lattice to mount to the internal surfaces of the electrically conductive panels.

3. The modular magnetically shielded room of claim 1 further comprising an outer wood frame; and wherein:
the outer wood frame is mounted to the external surfaces of the electrically conductive panels; and
the external mu-metal panels are mechanically coupled to the outer wood frame to mount to the external surfaces of the electrically conductive panels.

4. The modular magnetically shielded room of claim 1 further comprising internal mu-metal brackets; and wherein:
the internal mu-metal brackets mechanically couple to the internal mu-metal panels at the interfaces between the walls, the floor, and the ceiling.

5. The modular magnetically shielded room of claim 1 further comprising external mu-metal brackets; and wherein:
the external mu-metal brackets mechanically couple to the external mu-metal panels at the interfaces between the walls, the floor, and the ceiling.

6. The modular magnetically shielded room of claim 1 further comprising internal mu-metal cover strips and external mu-metal cover strips; and wherein:
the internal mu-metal cover strips couple adjacent ones of the internal mu-metal panels; and
the external mu-metal cover strips couple adjacent ones of the external mu-metal panels.

7. The modular magnetically shielded room of claim 1 wherein:
the internal mu-metal panels are arranged in a first layer and a second layer, the first layer comprising a set of the internal mu-metal panels arranged in a vertical orientation and the second layer comprising another set of the internal mu-metal panels arranged in a horizontal orientation; and
the first layer is coupled to the second layer.

8. The modular magnetically shielded room of claim 1 further comprising a door; and wherein:
one of the walls comprises an entry port and the door is mounted to the one of the walls at the entry port.

9. The modular magnetically shielded room of claim 8 wherein:
the door comprises an electrically conductive door panel, an internal door mu-metal panel, and an external door mu-metal panel;
when the door is in a closed position:
the electrically conductive door panel electrically couples to the electrically conductive panels of the walls;
the internal door mu-metal panel contacts the internal mu-metal panels mounted to the internal surfaces of the one of the walls; and
the external door mu-metal panel contacts the external mu-metal panels mounted to the external surfaces of the one of the walls.

10. The modular magnetically shielded room of claim 1 wherein at least one of the electrically conductive panels comprises a conduit port; and further comprising:
conduit that passes into the interior volume through the conduit port; and wherein:
the conduit carries at least one of a signaling link, a data link, a power link, or an electrical ground.

11. The modular magnetically shielded room of claim 1 wherein:
the flanges of the electrically conductive panels comprise screw ports; and
each of the electrically conductive panels is screwed to adjacent ones of the electrically conductive panels through the screw ports of the flanges to mechanically couple the electrically conductive panels to each other.

12. The modular magnetically shielded room of claim 1 further comprising support feet; and wherein:
the support feet are mounted to the external surfaces of the electrically conductive panels of the floor.

13. The modular magnetically shielded room of claim 1 wherein the electrically conductive panels and the electrically conductive brackets comprise aluminum and an electrically conductive surface coating.

14. The modular magnetically shielded room of claim 13 wherein the electrically conductive surface coating comprises an Alodine coating

15. The modular magnetically shielded room of claim 13 wherein the electrically conductive surface coating comprises a chromate coating.

16. The modular magnetically shielded room of claim 13 wherein the electrically conductive surface coating comprises a tin coating.

17. The modular magnetically shielded room of claim 13 wherein the electrically conductive surface coating comprises a copper coating.

18. The modular magnetically shielded room of claim 1 wherein:
the internal mu-metal panels and the external mu-metal panels comprise an alloy; and
the alloy comprises nickel, iron, copper, and chromium or molybdenum.

19. The modular magnetically shielded room of claim 1 wherein:
the internal mu-metal panels and the external mu-metal panels comprise an alloy; and
the alloy comprises nickel, molybdenum, silicon, and iron.

20. A method of manufacturing a modular magnetically shielded room to shield a magnetic field detection system from electromagnetic noise, the method of manufacturing comprising:
mechanically coupling electrically conductive panels to each other to form walls, a floor, and a ceiling of the modular magnetically shielded room, wherein mechanically coupling the electrically conductive panels to each other electrically couples the electrically conductive panels to each other;
mechanically coupling electrically conductive brackets to the electrically conductive panels at interfaces between the walls, the floor, and the ceiling to couple the walls, the floor, and the ceiling to each other, wherein mechanically coupling the electrically conductive brackets to the electrically conductive panels electrically couples the electrically conductive brackets to the electrically conductive panels;
mounting internal mu-metal panels to internal surfaces of the electrically conductive panels of the walls, the floor, and the ceiling; and
mounting external mu-metal panels to external surfaces of the electrically conductive panels of the walls, the floor, and the ceiling.
